(19) United States
(12) Patent Application Publication
(10) Pub. No.: US 2006/0282735 A1
(43) Pub. Date: Dec. 14, 2006

(54) Fasttest module

(75) Inventors: Chananiel Weinraub, Harzliya (IL); Daniel Sulc, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/135,983

(22) Filed: May 24, 2005

(51) Int. Cl. G01R 31/28; G06F 11/00

(52) U.S. Cl. 714/742

(57) ABSTRACT

In a method and system for testing a device, a tester provides a first plurality of test signals to the device. A test module includes a plurality of logic circuits operable to concurrently execute a plurality of test programs. The concurrent execution of the plurality of test programs generates a second plurality of test signals. The plurality of logic circuits control a plurality of switches in which each one of the plurality of switches is selectively controlled to provide one of the first plurality of test signals and the second plurality of test signals to/from the device.

### BACKGROUND

The present disclosure relates generally to test systems, and more particularly to a system and method for improving efficiency of testing devices.

The increasing functional complexity of electronic components and systems has made integrated circuit (IC) testing challenging, particularly under the constraints of making a continuous improvement in quality and a continuous reduction in cost. The cost of manufacturing a transistor continues to improve as predicted by Moore's Law. Test costs, however, have not generally followed the same price/performance curve as the transistor and are therefore becoming a higher percentage of the total manufacturing cost of a chip.

Today, manufacturers of automatic test equipment (ATE) offer test systems to address the increasingly complex task of testing advanced multi-function, ICs such as system-on-a-chip (SoC). However, many commercially available ATE systems are complex, proprietary, not easily flexible to meet changing test conditions, often require additional heat removal systems and typically cost several million dollars, thereby making them unattractive for use in a cost driven manufacturing environment. Recently, many semiconductor manufacturers and some ATE suppliers have introduced low cost test systems such as a very low cost tester (VLCT). The VLCT system may be used as a standalone test system and/or used in combination with a conventional ATE system. The VLCT systems typically provide lower test costs and are more flexible in meeting the changing test conditions, making them more attractive in the cost driven manufacturing environment.

The following United States Patent Applications describe various aspects of typical low cost test systems and are incorporated herein by reference: 1) US Patent Application No. 20050055615, Agashe, et al., entitled “At-speed ATPG Testing And Apparatus For SoC Designs Having Multiple Clock Domain Using A VLCT Test Platform”, 2) US Patent Application No. 20050044445, Boose, et al., entitled “System And Method For Testing A Device”, 3) US Patent Application No. 20050060612, Patrick Bohan, entitled “System And Method For Testing A Device”.

However, many of the VLCT systems provide a limited amount of performance and have a limited capacity. For example, some VLCT systems may have a limited data throughput for testing and may include a limited number of input/output (I/O) channels available for testing. Some of these limitations may result in increasing the time and therefore reducing the efficiency to test each device under test (DUT). The additional time needed for testing each device is magnified at the manufacturing process level when a very large number of chips may be tested in a day. As a result, some of the limitations of the VLCT systems may inadvertently slow down the production rate and may contribute to an overall increase in the cost of testing.

Therefore, a need exists to provide an efficient method and system for testing electrical devices. Additionally, a need exists to provide an improved technique for reducing the time to test each DUT preferably while maintaining compatibility with an existing or legacy test system for testing the DUT. Furthermore, a need exists to reduce overall cost of testing. Accordingly, it would be desirable to provide an improved test system for testing devices, absent the disadvantages found in the prior methods discussed above.

### SUMMARY

The foregoing need is addressed by the teachings of the present disclosure, which relates to a system and method for testing a device. According to one embodiment, in a method and system for testing a device, a tester provides a first plurality of test signals to the device. A test module includes a plurality of logic circuits operable to concurrently execute a plurality of test programs. The concurrent execution of the plurality of test programs generates a second plurality of test signals. The plurality of logic circuits control a plurality of switches in which each one of the plurality of switches is selectively controlled to provide one of the first plurality of test signals and the second plurality of test signals to the device.

In one aspect of the disclosure, a test module for testing a device includes a host interface logic circuit to receive a plurality of test programs for testing the device. A plurality of pattern control logic circuits are coupled to receive the plurality of test programs and stored the programs in memory. The plurality of pattern control logic circuits concurrently execute the plurality of test programs and generate a plurality of test signals for testing the device. A plurality of I/O control circuits are operable to control a voltage level of the plurality of test signals, the I/O control circuits being coupled to a corresponding one of the plurality of pattern control logic circuits. A plurality of switches are coupled to the plurality of I/O control circuits to receive the plurality of test signals. The plurality of switches are selectively controlled by the plurality of pattern control logic circuits to communicate the plurality of test signals to the device.

Several advantages are achieved by the method and system according to the illustrative embodiments presented herein. The embodiments advantageously provide for an efficient technique to concurrently perform at-speed tests for one or more devices. This advantageously enables manufacturing facilities to add an improved test module to a new and/or existing/legacy test system to reduce overall test time, thereby reducing the overall testing costs and enabling increased production.

### BRIEF DESCRIPTION OF THE DRAWINGS

FIG. 1A illustrates an improved test system for testing a device, according to an embodiment;

FIGS. 1B and 1C are multiple view diagrams illustrating details of the test head assembly of FIG. 1A, according to an embodiment;

FIG. 2A is a block diagram illustrating additional details of a test module of FIG. 1A, according to an embodiment;

FIG. 2B illustrates additional details of the electrical coupling between the test head, the test module, and the DUT of FIG. 1A, according to an embodiment;

FIG. 2C is a block diagram illustrating additional details of the logic module of FIG. 2A, according to an embodiment;

FIG. 3 is a block diagram illustrating an implementation of the logic module of FIG. 2A, according to an embodiment; and

FIG. 4 is a flow chart illustrating a method for testing a plurality of devices, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements.

Many commercially available, advanced, multi-function test systems are often very complex, bulky, require additional heat removal systems and typically cost several million dollars. Some of the lower cost test systems may offer more flexibility and may be more affordable but may be limited by their performance and capacity. The performance and capacity limitation of the lower cost tester may negatively impact the production rate for manufacturing the device, thereby increasing the overall cost of testing. This problem may be addressed by an improved system and method to test a device, especially in a manufacturing environment. In the improved system and method, a test module concurrently executes multiple test programs in parallel to concurrently provide one or more test signals for testing one or more devices. The concurrent operation improves performance and capacity of the test system.

According to one embodiment, in a method and system for testing a device, a tester provides a first plurality of test signals to the device. A test module includes a plurality of logic circuits operable to concurrently execute a plurality of test programs. The concurrent execution of the plurality of test programs generates a second plurality of test signals. The plurality of logic circuits control a plurality of switches in which each one of the plurality of switches is selectively controlled to provide one of the first plurality of test signals and the second plurality of test signals to the device.

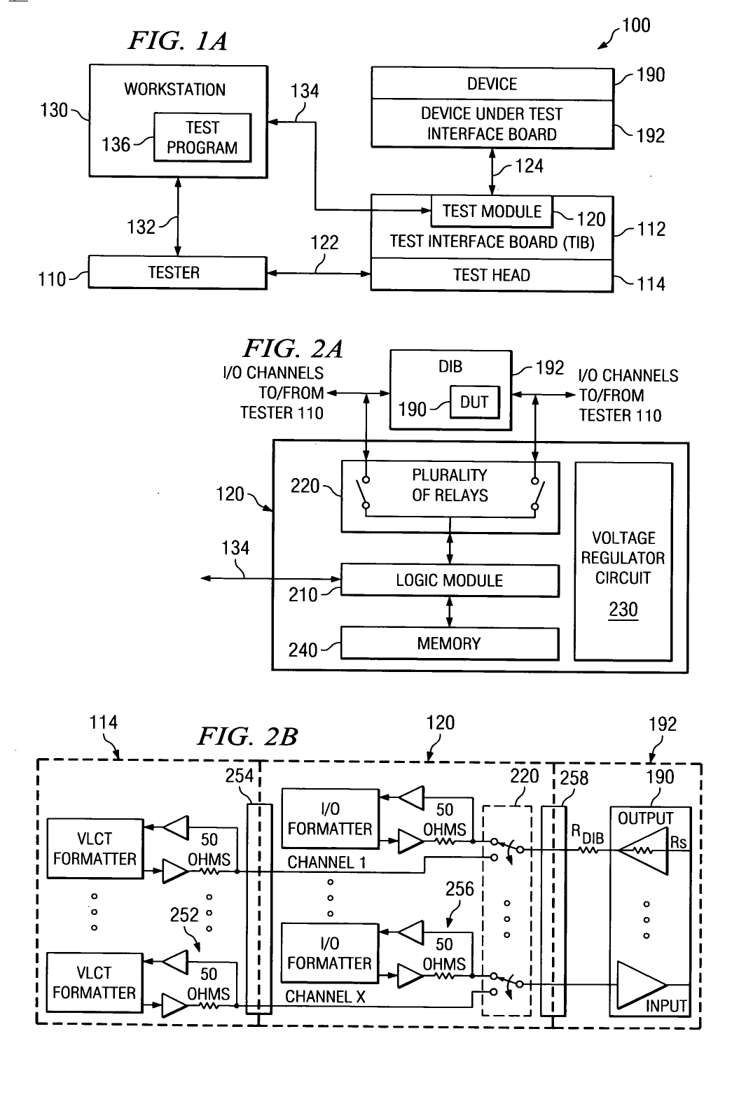

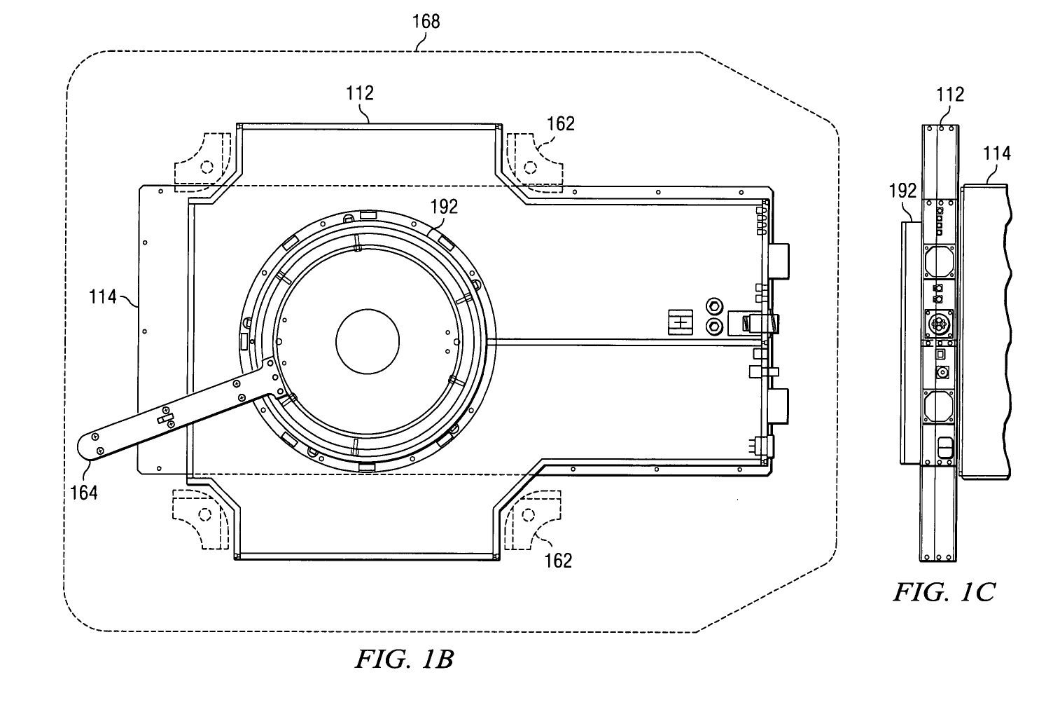

FIG. 1A illustrates a block diagram of an improved test system 100 for testing a device 190, according to an embodiment. The test system 100 includes a tester 110 operable to communicate a first plurality of test signals (not shown) to a test head 114 via one or more electrical couplers 122 (such as conductors, cables, lines, pins, links, traces, buses, and the like). The test head 114 is coupled to a tester interface board (TIB) 112 to communicate the first plurality of test signals to a test module 120. In a particular embodiment, the test module 120, which may also be referred to as a FastTest module, is mounted on and electrically coupled to the TIB 112. The test module 120 is operable to communicate a second plurality of test signals (not shown) to a device interface board (DIB) 192 via one or more electrical couplers 124 (such as pins, conductors, cables, lines, links, traces, buses, and the like). The device 190, which may be also referred to as a device under test (DUT), is positioned/placed and electrically coupled to the DIB 192 by a handler (or prober) (not shown). Additional details of the test module 120 are described with reference to FIGS. 2A, 2B and 2C.

The TIB 112 is removable from or secured to a test head 114 of the tester 110. That is, the TIB 112 and hence the test module 120 is secured to the test head 114 in a removable manner or the TIB 112 is ‘removably secured’ to the test head 114. The DIB 192 is removably secured to the TIB 112 by a known type of docking mechanism. For example, in a docking system deployed in many pressure cookers, a pressure cooker lid (illustrative of the DIB 192) is removably secured to the pressure cooker base (illustrative of the test head 114 and the TIB 112) by a process using ridge alignment, vertical pressure and handle rotation. In a docked or secured position the DUT 190 is electrically coupled to the tester 110 and the test module 120. Since the size, layout and arrangement of the test head 114 may vary depending on the manufacturer, model/type and size of the tester 119, the particular size and layout of the TIB 112 may vary and may be adapted to meet the specifications for each testing application. Additional details of a test head assembly that includes the test head 114, the TIB 112 and the DIB 192 (shown without the DUT 190) are described with reference to FIGS. 1B and 1C.

In a non-depicted exemplary embodiment, the test module 120 may be mounted on and electrically coupled to the DIB 192 instead of the TIB 112. In this embodiment, the implementation of the DIB 192 may vary with each type of device tested.

A workstation 130 is electrically coupled to the tester 110 via one or more communications links 132 and to the test module 120 via one or more communications links 134. The links 132 and 134 may be implemented by using all or a portion of a bus connection, one or more local area networks (LAN's), metropolitan area networks (MAN's), wide area network (WAN's), a global network such as the Internet, any other appropriate wire line, wireless or other similar communication link. In a particular embodiment, the workstation 130 is a programming device, such as a computer system, operable to generate a test program 136. Multiple programs may be developed to test various aspects of the DUT 190. The workstation 130 may include conversion tools to generate an executable and/or downloadable version from a source code of the test program 136.

In a particular embodiment, the test program 136 includes a stimuli logic to provide the second plurality of test signals to the device, a compare logic to receive response signals from the device, and a decision logic to determine whether the device passes or fails the testing. Execution of the test program 136 results in applying test stimuli (also referred to as test vectors) to the DUT 190. In a particular embodiment, the test stimuli may be in the form of providing the first and second plurality of test signals to the DUT 190. The test vectors for a particular test may define a sequence of fixed input values and expected output values for a circuit being tested. If the response from the DUT 190 to the test stimuli does not match the expected output values then the DUT 190 may be identified as defective. Test related data such as pass/fail results, time/event data, diagnostic data, and logging data may be provided to the workstation 130 for further analysis.

In a particular embodiment, the first plurality of test signals may include various well known test signals types including alternating current (AC) and/or direct current (DC), analog and/or digital, time and/or frequency, synchronous and/or asynchronous, pulse, clock and similar others. In one embodiment, the first set of test signals include a DC power signal to power the device 190 and a low speed digital signal having a frequency less than approximately 30 MHz.

In a particular embodiment, the second plurality of test signals may include test signals having at least one common property, attribute or characteristic. For example, each one of the second plurality of test signals may be a high-speed digital signal having a clock frequency that is greater than approximately 40 MHz and less than approximately 100 MHz. The specific values for the clock frequency may change with technology.

Various types of the test program 136 may be developed to test device features. For example, the types of test programs may include a scan I/O program to test internal circuitry, a high-speed data capture program to capture device digital outputs such as outputs of an analog-to-digital converter included in the device 190, a high-speed digital data test program to provide digital inputs to the DUT 190 such as digital inputs of a digital-to-analog converter included in the device 190, and similar others.

The access to test the internal circuitry within the DUT 190 may be limited by the physical inputs and outputs of the device, especially during manufacturing testing. Additional internal embedded test circuitry such as scan chain circuitry may be added to the DUT 190 to improve the internal testability. A wrapper cell is described as the circuitry attached to the functional elements of a core to provide flow paths for the test signals. The scan I/O program includes chaining several wrapper cells together in a chip register in order to scan test data in and out of the circuit.

In a particular embodiment, the tester 110 is a very low cost tester having limited performance and/or having limited I/O channel capacity, thereby increasing the test time to test each device. For example, the tester 110 may not have memory to store the test program 136. The effective clock rate to communicate the first plurality of test signals to the DUT 190 may be limited to 30 MHz or less. The number of scan I/O chains may be limited to eight.

FIGS. 1B and 1C are multiple view diagrams illustrating details of the test head 114, the TIB 112 and the DIB 192 (shown without the DUT 190) of FIG. 1A, according to an embodiment. Referring to FIG. 1B, the TIB 112 is removably secured to the test head 114 (outline shown) by a docking plate 168 and one or more removable clamp devices 162. The DIB 192 is removably secured to the TIB 112 by a docking assembly 164 having a circular shape with a handle. FIG. 1C illustrates a cross sectional view of the test head 114, the TIB 112 and the DIB 192.

FIG. 2A is a block diagram illustrating additional details of the test module 120 of FIG. 1, according to an embodiment. The test module 120 includes a logic module 210 operable to provide the second plurality of test signals to the device 190. The logic module 210 communicates with the workstation 130 via the communication link 134. The test program 136 is downloaded to the logic module 210 via the link 134 and stored in a memory 240 for later execution. Sizing of the memory 240 may be determined by factors such as n number of I/O channels, number of tests, and number of test vectors. In a particular embodiment, a built-in self-test (BIST) may be performed for the memory 240 before storing the test program 136.

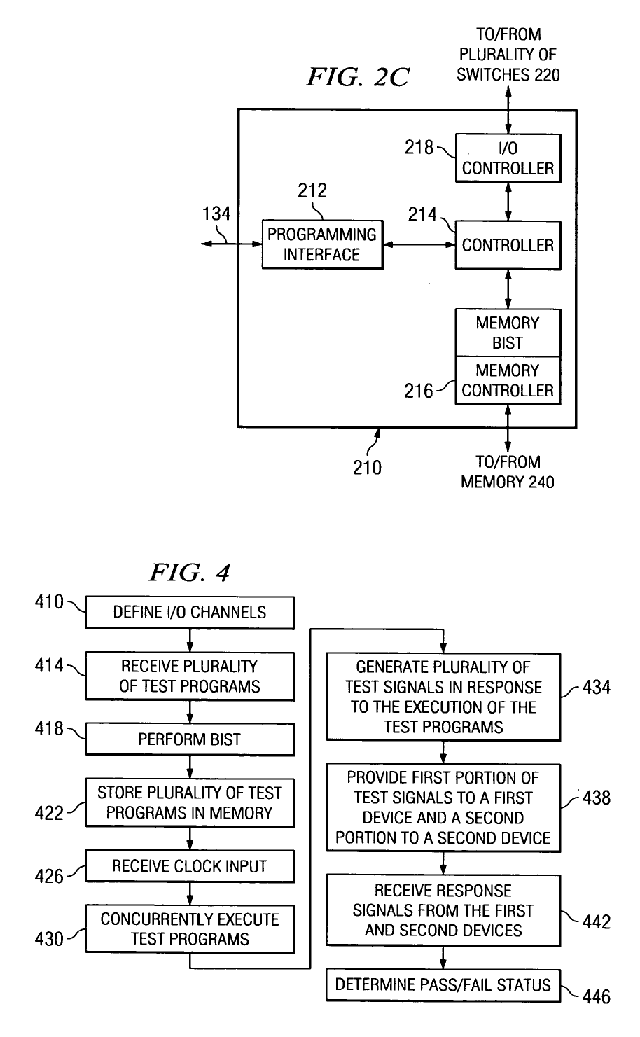

In a particular embodiment, the logic module 210 is implemented by one or more field programmable gate arrays (FPGAs), which are operable to execute or run one or more test programs corresponding to each test. The FPGAs may be programmed to perform several tests concurrently and at the highest possible clock frequencies, thereby reducing time to test each device. Additional details of the logic module 210 are described with reference to FIG. 2C. Also, additional detail of a multiple FPGA implementation of the logic module 210 is described with reference to FIG. 3.

In a particular embodiment, the test system 100 provides n I/O channels to communicate the first and second plurality of signals to the device 190. The particular value of n, which is an integer, may vary by application. A plurality of switches 220 are controlled by the logic module 210. The number of switches included in the plurality of switches 220 corresponds to the n number of I/O channels. In a non-depicted exemplary embodiment, the plurality of switches 220 is implemented as a ‘n×n’ relay matrix using reed relays. The relay matrix enables flexible routing of stimulus/response signals to/from the device. The relay matrix is thus operable to intercept and arbitrate access to any or all of the n I/O channels. Additional details of the electrical coupling between various components of the test system 100 are described with reference to FIG. 2B.

The test module 120 includes a voltage regulator circuit 230 to provide a scalable voltage signal to the logic module 210 and the plurality of switches 220. In an alternative embodiment, level shifters may be added serially to the logic module 210 to enable testing devices with different I/O voltages.

FIG. 2B illustrates additional details of the electrical coupling between the test head 114, the test module 120 and the DUT 190 of FIG. 1A, according to an embodiment. In the depicted exemplary embodiment, each one of the n I/O channels of the tester 110 (not shown) has a 50 ohm source termination resistor 252 to match a 50 ohm signal transmission line. A first plurality of connectors 254 such as pogo style pin connectors communicate the first plurality of test signals to the test module 120. In a particular embodiment, the first plurality of connectors 254 may include conductive traces on the TIB 112 (not shown). Similarly, each one of n I/O channels of the test module 120 has a 50 ohm source termination resistor 256 to match a 50 ohm signal transmission line. Each one of the plurality of switches 220 is operable to select one of the two test signals, e.g., the first and second plurality of test signals. The selected signal is communicated to the DIB 192 and the DUT 190 via a second plurality of connectors 258 such as pogo style pin connectors.

FIG. 2C is a block diagram illustrating additional details of the logic module 210 of FIG. 2A, according to an embodiment. In the depicted embodiment, the logic module 210 includes a programming interface 212 coupled to the link 134. A controller 214 receives the test programs 136 from the programming interface 212 and controls the operation of a memory controller 216 and an I/O controller 218 as directed by the test program 136. The test program 136 includes both pattern set data and timing data. Thus, the test technique is clock cycle driven, thereby enabling at-speed testing of devices. In a non-depicted exemplary embodiment, a free running clock signal having a predefined clock frequency may be generated internally within the logic module 210 and/or may be acquired externally by the logic module 210 to perform at-speed testing at multiple clock frequencies. In one embodiment, the predefined clock frequency is greater than approximately 40 MHz and less than approximately 220 MHz. In order to execute test program 136 at the predefined frequency, scan clocks, scan inputs, and scan outputs are mapped to corresponding I/O channels. The memory controller 216 controls the operation of the memory 240 and the I/O controller 218 controls the operation and timing of the plurality of switches 220. A circuit to test memory, e.g., a built-in self-test, may be included in the logic module 210.

FIG. 3 is a block diagram illustrating an implementation of the logic module 210 of FIG. 2A, according to an embodiment. In the depicted embodiment, a plurality of FPGAs are used in the implementation. In a particular embodiment, the logic module 210 includes a plurality of logic circuits coupled in parallel to facilitate concurrent processing of the test programs. The concurrent parallel processing of test programs advantageously reduces the time to test each device by enabling a faster execution of the tests (e.g., measured in terms logic functions performed in a predetermined amount of time) and by executing more test programs in parallel. The execution speed may be increased by selecting a higher shift frequency. For example, with concurrent processing more, than 8 scan chains may be processed without a corresponding reduction in the test pattern execution rate. The number of test programs executed, e.g., number of scan chains processed, may depend on the size of the memory 240 and the number of logic circuits in parallel.

In the depicted embodiment, the logic module 210 includes a first logic circuit 310, a second logic circuit 320, a third logic circuit 330 and a fourth logic circuit 340 coupled in parallel. The number of logic circuits included may depend on the desired performance and the n number of I/O channels. In the depicted embodiment, n=512 I/O channels and the number of logic circuits included in the logic module 210 is 4. Thus, each logic circuit controls 128 I/O channels. The particular number of I/O channels controlled by each logic circuit may vary and depend on each application.

A fifth logic circuit 350 is coupled to the workstation 130 (not shown) via the link 134. The fifth logic circuit 350 is coupled to each one of the first, second, third and fourth logic circuits 310, 320, 330 and 340 by a communications link 362. Each one of the plurality of logic circuits is operable to provide a corresponding portion of the second plurality of test signals. In a particular embodiment, each one of the first, second, third, fourth and fifth logic circuits 310, 320, 330, 340 and 350 is implemented by using five corresponding FPGAs operable to concurrently operate in parallel.

In a particular embodiment, the fifth logic circuit 350 is a host interface FPGA. It performs the functions of the programming interface 212. In the depicted embodiment, the fifth logic circuit 350 receives a clock signal input 352. One or more clock signals may be received to perform tasks such as synchronization, shifting of data and the like. In one embodiment, the clock signal input 352 may be used to synchronize the time of the first and second plurality of test signals and maintain coherency within the test system 100. A memory device 354, coupled to the fifth logic circuit 350, stores host interface communication related data. In the depicted embodiment, the communication link 134 is implemented as a universal serial bus (USB) 356 and/or a JTAG link 358.

In the depicted embodiment, the first logic circuit 310 performs substantially the same functions performed by the controller 214 but on a fewer number of I/O channels. The first logic circuit 310 includes a first pattern control logic circuit 312 operable to execute a downloaded version of the test program 136.

The fifth logic circuit 350 receives the test program 136 from the workstation 130 and stores the program 136 in a first memory device 314 coupled to the first pattern control logic circuit 312. A first I/O control circuit 316 performs substantially the same functions performed by the I/O controller 218 but on a fewer number of channels. The first I/O control circuit 316 performs timing, format and voltage level control for a portion of the second plurality of test signals. In the depicted embodiment, the first I/O control circuit 316 receives 128 input channels and provides 128 output channels to the pattern control logic circuit 312 and controls 128 I/O channels of the plurality of switches 220 implemented in the form of the relay matrix.

Similar to the first logic circuit 310, each of the second, third and fourth logic circuits 320, 330 and 340 include corresponding second, third, fourth pattern control logic circuits 322, 332, 342; second, third, fourth memory devices 324, 334, 344; and second, third, fourth I/O control circuits 326, 336, 346.

In the depicted embodiment, another device under test (ADUT) 198 is concurrently tested with the device 190. That is, a first portion of the second plurality of test signals may be directed to the device 190 and a second portion of the second plurality of test signals may be directed to the ADUT 198 under the control of the test program 136. Thus, a plurality of test devices having a total number of I/O channels not greater than n may be tested concurrently. In one embodiment, each one of the plurality of devices is one of a microprocessor, a digital signal processor, a radio frequency chip, a memory, a microcontroller and a system-on-a-chip or a combination thereof.

A tradeoff may be made between number of devices tested concurrently and number of scan chains included in the program 136, with the number of devices tested concurrently being inversely proportional to the number of scan chains processed. In a particular embodiment, number of scan chains processed may be increased by utilizing a scan data compression technique that uses 8 scan chains per 128 consecutive I/O channels.

As described earlier, the number of switches included in the plurality of switches 220 corresponds to the n number of I/O channels. Each one of the plurality of switches 220 is controlled to selectively provide one test signal from the first plurality of test signals and the second plurality of test signals. That is, each of the plurality of switches 220 is switchable to an on state or an off state to enable or disable the signal flow. For example, in an off state the switch may enable one of the first plurality of test signals to pass through to the device 190 and in an on state the switch may enable one of the second plurality of test signals to pass through to the device 190. In a particular embodiment, the n number of switches included in the plurality of switches 220 may be controlled by any one of the first, second, third and fourth logic circuits 310, 320, 330 and 340.

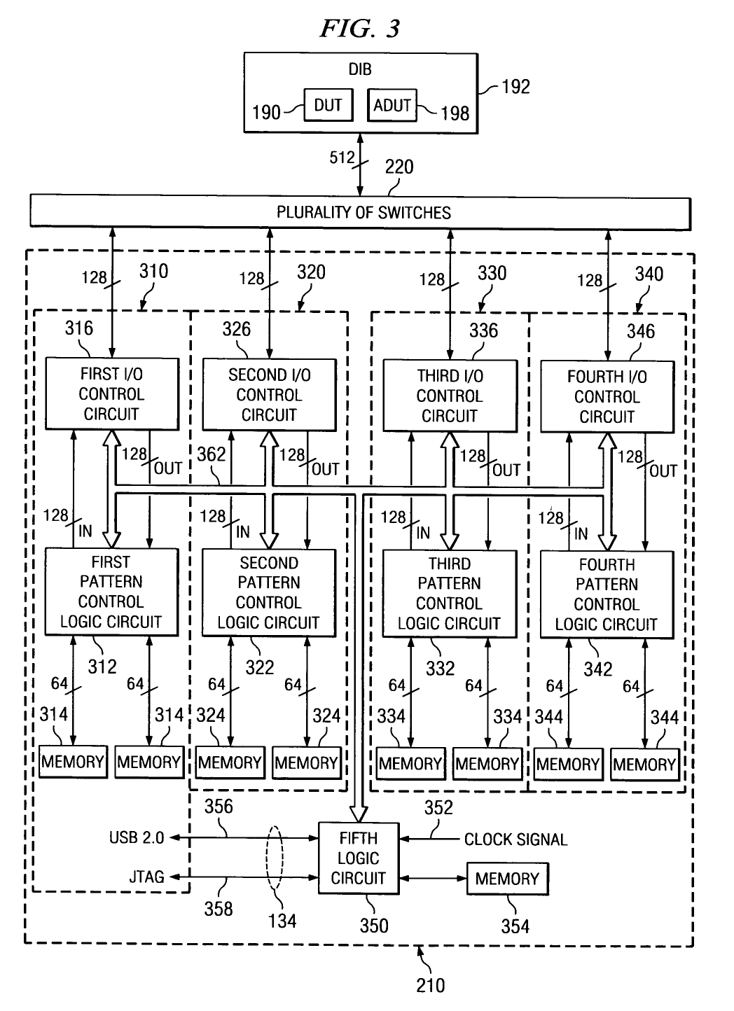

FIG. 4 is a flow chart illustrating a method for testing a plurality of devices, according to an embodiment. At step 410, each one of a plurality of input/output channels coupled to the plurality of devices, e.g., devices 190 and 198, is defined. In a particular embodiment, the I/O channel may be defined as an input, an output or a bi-directional channel. At step 414, a plurality of test programs are received to test the plurality of devices. At step 418, a built-in self-test (BIST) is performed for a memory, e.g., the memory 240, before storing the plurality of test programs. In one embodiment, the BIST may be automatically performed during initial power-on condition. At step 422, the plurality of test programs are stored into the memory. At step 426, a clock input having a predefined frequency is received. At step 430, the plurality of test programs are executed in a substantially concurrent manner. At step 434, a plurality of test signals, e.g., the second plurality of test signals, are generated in response to the execution of the plurality of test programs and receiving the clock input. At step 438, a first portion of the plurality of test signals is provided to a first device and a second portion of the plurality of test signals is provided to a second device in a substantially concurrent manner. At step 442, a first response signal from the first device and a second response signal from the second device is received. The first and second responses may be stored in the same memory used to store the plurality of test programs.

Various steps described above may be added, omitted, combined, altered, or performed in different orders. For example, step 426 may be deleted if an internally generated clock signal is available. As another example, step 446 may be added. At step 446, the first and the second response signals are compared to a predefined plurality of signals to determine a pass or fail status of each one of the plurality of devices.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of FPGAs, those of ordinary skill in the art will appreciate that the processes disclosed are capable of being implemented using hardware, software, and firmware components including system-on-a-chip (SoC) and/or a combination thereof.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A test system for testing a device, the test system comprising:
a tester providing a first plurality of test signals to the device; and
a test module including:
a plurality of logic circuits providing a second plurality of test signals to the device;
a plurality of switches controlled by the plurality of logic circuits, wherein each one of the plurality of switches selectively provides one of the first plurality of test signals and the second plurality of test signals to the device.

2. The system of claim 1, wherein the plurality of logic circuits includes:
a first logic circuit to execute a first test program, wherein execution of the first test program generates a first portion of the second plurality of test signals; and
a second logic circuit to execute a second test program, wherein execution of the second test program generates a second portion of the second plurality of test signals, wherein the first test program and second test program are executed substantially concurrently to reduce time to test the device.

3. The system of claim 2, wherein the first portion and the second portion of the second plurality of test signals are communicated substantially concurrently to the device via the plurality of switches to reduce time to test the device.

4. The system of claim 2, wherein the plurality of logic circuits include:
a first memory coupled to the first logic circuit to store the first test program; and
a second memory coupled to the second logic circuit to store the second test program.

5. The system of claim 2, wherein the first portion of the second plurality of test signals and the second portion of the second plurality of test signals are substantially concurrently provided to the device and another device coupled to the test module, wherein the device and the another device are concurrently tested to reduce test time.

6. The system of claim 1, wherein each one of the second plurality of test signals is a high-speed digital signal having a frequency greater than approximately 40 MHz and less than approximately 100 MHz.

7. The system of claim 1, wherein the test module is coupled to a programming device, wherein the programming device generates a plurality of test programs corresponding to each test type for testing the device.

8. The system of claim 7, wherein at least one of the plurality of test programs includes a stimuli logic to provide the second plurality of test signals to the device, a compare logic to receive response signals from the device, and a decision logic to determine whether the device passes or fails the testing.

9. The system of claim 7, wherein at least one of the plurality of test programs is one of a scan I/O program, a high-speed data capture program, and a high-speed digital data test program or a combination thereof.

10. The system of claim 1, wherein the plurality of logic circuits, the plurality of switches, a first plurality of terminals for communicating the first plurality of test signals and a second plurality of terminals for communicating the second plurality of test signals are mounted on a tester interface board (TIB), the TIB being removably secured to a test head of the tester.

11. The system of claim 10, wherein the device is electrically coupled to a device interface board (DIB), wherein the DIB is removably secured to the interface board, wherein the test board is electrically coupled to the first and second plurality of terminals for communicating the first and second plurality of test signals to the device.

12. The system of claim 1, wherein the test module further comprises:
a voltage regulator providing a scalable voltage signal to the plurality of logic circuits and the plurality of switches.

13. The system of claim 1, wherein test module further comprises:
a phase locked loop circuit to generate an internal clock signal of a first predefined frequency; and
a shift clock circuit operable to receive a clock signal having a second predefined frequency.

14. The system of claim 1, wherein the device is one of a microprocessor, a digital signal processor, a radio frequency chip, a memory, a microcontroller and a system-on-a-chip or a combination thereof.

15. A method for testing a plurality of devices, the method comprising:
defining each one of a plurality of input/output channels coupled to the plurality of devices;
receiving a plurality of test programs to test the plurality of devices;
conducting a self-test for a memory operable to store the plurality of test programs;
storing the plurality of test programs into the memory;
receiving a clock input having a predefined frequency;
executing the plurality of test programs in a substantially concurrent manner;
generating a plurality of test signals in response to the execution of the plurality of test programs and receiving the clock input;
providing a first portion of the plurality of test signals to a first device and a second portion of the plurality of test signals to a second device in a substantially concurrent manner; and
receiving a first response signal from the first device and a second response signal from the second device.

16. The method of claim 15, further comprising:
comparing the first and the second response signals to a predefined plurality of signals to determine a pass or fail status of each one of the plurality of devices.

17. The method of claim 15, wherein at least one of the plurality of devices is one of a microprocessor, a digital signal processor, a radio frequency chip, a memory, a microcontroller and a system-on-a-chip or a combination thereof.

18. A test module for testing a device, the test module comprising:
a host interface logic circuit to receive a plurality of test programs for testing the device;
a plurality of pattern control logic circuits coupled to receive the plurality of test programs, wherein the plurality of pattern control logic circuits concurrently execute the plurality of test programs and generate a plurality of test signals for testing the device;
a plurality of input/output (I/O) control circuits coupled to a corresponding one of the plurality of pattern control logic circuits, wherein the plurality of I/O control circuits adjust voltage levels of the plurality of test signals; and
a plurality of switches coupled to receive the plurality of test signals, wherein the plurality of switches are selectively controlled by a corresponding one of the plurality of pattern control logic circuits to communicate the plurality of test signals to the device.

19. The test module of claim 18, wherein the device is one of a microprocessor, a digital signal processor, a radio frequency chip, a memory, a microcontroller and a system-on-a-chip or a combination thereof.

20. The test module of claim 18, wherein a plurality of memory circuits are coupled to a corresponding one of the plurality of pattern control logic circuits to store the plurality of test programs.
